(19) United States
(12) Patent Application Publication
(10) Pub. No.: US 2010/0212727 A1
(43) Pub. Date: Aug. 26, 2010

(54) APPARATUS AND METHODS FOR CONTINUOUSLY GROWING CARBON NANOTUBES AND GRAPHENE SHEETS

(76) Inventor: Ji Ung LEE, Niskayuna, NY (US)

Correspondence Address: HESLIN ROTHENBERG FARLEY & MESITI PC, 5 COLUMBIA CIRCLE, ALBANY, NY, 12203, US

(21) Appl. No.: 12/709,718

(22) Filed: Feb. 22, 2010

Related U.S. Application Data
(60) Provisional application No. 61/155,724, filed on Feb. 26, 2009.

(51) Int. Cl. H01L 31/00; D01F 9/12; H01B 1/04; C01B 31/04; B01J 19/00; B01J 19/08; F28D 21/00; H01L 33/04

(52) U.S. Cl. 136/252; 423/447.1; 423/447.2; 252/502; 423/448; 422/198; 422/186.04; 422/208; 257/13; 977/742; 977/842; 257/E33.013

(57) ABSTRACT

A method for continuously growing carbon nanotubes may include providing a melt comprising carbon and a catalyst at a temperature between about 1,200 degrees Celsius and about 2,500 degrees Celsius, selecting a carbon nanotube seed having at least one of a semiconductor electrical property and a metallic electrical property from a plurality of carbon nanotube seeds, contacting the selected carbon nanotube seed to a surface of the melt, and moving the selected carbon nanotube seed away from the surface of the melt at a rate operable to continuously grow a carbon nanotube, and continuously growing the carbon nanotube having the selected electrical property. Method for continuously growing a graphene sheet, and apparatus for continuously growing carbon nanotubes and graphene sheets are also disclosed.

### CLAIM TO PRIORITY

This application claims the benefit of U.S. Provisional Application Ser. No. 61/155,724, filed Feb. 26, 2009, the entire subject matter of which is incorporated herein by reference.

### FIELD OF THE INVENTION

This invention relates generally to carbon nanotubes and graphene sheets, and more particularly to apparatus and methods for continuously growing carbon nanotubes and graphene sheets.

### BACKGROUND OF THE INVENTION

Conventional techniques for forming carbon nanotubes are limited to the growth of short length nanotubes without the ability to control the diameter or the electronic properties of the resulting carbon nanotubes. The predominant technique used to grow carbon nanotubes is based on chemical vapor deposition (CVD) using catalytic metal nanoparticles, also known as the Vapor Liquid Solid growth technique. For example, an iron (Fe) nanoparticle serves as the nucleation site for carbon nanotubes. As carbon atoms, both dissolved and those that are on the surface, reach a critical concentration, the carbon atoms aggregate into molecules and precipitate out as a nanotube. Initially, carbon atoms take the shape of the end-cap. As more carbon atoms are added, the precipitated structure takes on a well-defined structure of a nanotube.

A catalyst-free, synthetic simulation method for producing carbon nanotubes is described in Zhang et al., “Draw out Carbon Nanotube from Liquid Carbon”, available on-line at arXiv.org, Condensed Matter, Materials Science, at http://fujimac.t.u-tokyo.ac.jp/hoshi/doc/zhang_CNT_condmat0604043.pdf, 14-pages, April 2006. The method includes plunging a carbon nanotube into liquid carbon at a temperature of about 4,500 degrees Celsius with cooling in high pressure helium atmosphere and drawing out with a considerable velocity. The result of the simulations show that carbon nanotubes can be elongated steadily.

A report of the growth of a multi-walled carbon nanotube (MWNT) inside a larger MWNT has been described in Jensen, Mickelson, Han, and Zettle, “Current-Controlled Nanotube Growth and Zone Refinement”, Appl. Phys. Lett. 86, 173107, 2005. This was accomplished by passing a current through the MWNT containing a partially filled cobalt nanoparticle. In their experiment, Co particles were found naturally inside MWNTs as a byproduct of their nanotube growth technique. As such, the Co particles have in them carbon atoms that were dissolved during growth at elevated temperatures. The current passing through the MWNT melts and transports the Co catalyst, leaving behind a smaller diameter MWNT in its wake. The process terminates when the carbon initially dissolved in the Co particle runs out.

Presently, there are no synthesis techniques that yield large sheets of graphene. The predominant technique utilizes mechanical exfoliation of graphite bulk to yield micron size graphene flakes which are not suitable for large scale manufacturing.

There is a need for further development on the growth of carbon nanotubes and graphene sheets, and more particularly to apparatus and methods for continuously growing carbon nanotubes and graphene sheets.

### SUMMARY OF THE INVENTION

In a first aspect, the present invention provides an apparatus for continuously growing a carbon nanotube from a carbon nanotube seed. The apparatus includes a housing having a chamber, crucible for containing a carbon catalyst melt disposed in the housing, and heating means for heating the carbon catalyst melt to a temperature between about 1,200 degrees Celsius and about 2,500 degrees Celsius. A controller controls movement of the carbon nanotube seed to contact a surface of the carbon catalyst melt maintained at the temperature between about 1,200 degrees Celsius and about 2,500 degrees Celsius at a rate operable to continuously grow the carbon nanotube.

In a second aspect, the present invention provides a method for continuously growing a carbon nanotube. The method includes providing a melt comprising carbon and a catalyst at a temperature between about 1,200 degrees Celsius and about 2,500 degrees Celsius, selecting a carbon nanotube seed having at least one of a semiconductor electrical property and a metallic electrical property from a plurality of carbon nanotube seeds, contacting the selected carbon nanotube seed to a surface of the melt, moving the selected carbon nanotube seed away from the surface of the melt at a rate operable to continuously grow a carbon nanotube, and continuously growing the carbon nanotube having the selected electrical property.

In a third aspect, the method may include forming a plurality of the continuously grown carbon nanotubes into an electrical cable, or a product having a binder and plurality of the continuously grown carbon nanotubes as high strength fibers.

In a fourth aspect, the present invention provides an apparatus for continuously growing a graphene sheet from a graphene seed. The apparatus includes a housing having a chamber, crucible for containing a carbon catalyst melt disposed in said chamber of said housing, heating means for heating the carbon catalyst melt to a temperature between about 1,200 degrees Celsius and about 2,500 degrees Celsius, and a controller for controlling movement of the graphene seed to contact a surface of the carbon catalyst melt and controlling movement of the graphene seed away from the surface of the carbon catalyst melt at the temperature between about 1,200 degrees Celsius and about 2,500 degrees Celsius and at a rate operable to continuously grow the graphene sheet.

In a fifth aspect, the present invention provides method for continuously growing a graphene sheet. The method includes providing a melt comprising carbon and a catalyst at a temperature between about 1,200 Celsius and about 2,500 degrees Celsius, providing a graphene seed, contacting the graphene seed to a surface of the melt, moving the graphene seed away from the surface of the melt at a rate operable to continuously grow the graphene sheet, and continuously growing the graphene sheet.

In a sixth aspect, the method may include forming an integrated circuit with the graphene sheet, or forming an optoelectronic device with the graphene sheet.

In a seventh aspect, the present invention may include cables, integrated circuits, and optoelectronic device which employ the above-noted continuously grown carbon nanotubes and graphene sheets.

### BRIEF DESCRIPTION OF THE DRAWINGS

The subject matter which is regarded as the invention is particularly pointed out and distinctly claimed in the concluding portion of the specification. The invention, however, may best be understood by reference to the following detailed description of various embodiments and the accompanying drawings in which:

FIG. 1 is a diagrammatic illustration of one embodiment of an apparatus for continuously growing a carbon nanotube in accordance with one aspect of the present invention;

FIG. 2 is a diagrammatic illustration of one embodiment of an apparatus for continuously growing a graphene sheet in accordance with one aspect of the present invention;

FIG. 3 is flowchart of one embodiment of a process for continuously growing a carbon nanotube in accordance with one aspect of the present invention; and

FIG. 4 is flowchart of one embodiment of a process for continuously growing a graphene sheet in accordance with one aspect of the present invention.

### DETAILED DESCRIPTION OF THE INVENTION

Various aspects for the present invention are generally directed to apparatus and methods for continuously growing carbon nanotubes and graphene sheets having predetermined properties. Such carbon nanotubes may be assembled into electrical cables for transmission of electricity. Graphene, one-atom-thick sheet of graphite densely packed in a honeycomb crystal lattice, may be used as a replacement for silicon (Si), the current dominant material for electronics and photovoltaic materials.

More particularly, the various aspects of the present invention are directed to synthesis techniques for carbon nanotubes and graphene sheets that is scalable for mass production and that overcomes conventional synthesis techniques for carbon nanotubes that are limited to the growth of short length nanotubes without the ability to control the diameter or the electronic properties of the carbon nanotube. The various aspects of the present invention may also provide growth techniques that can yield potentially unlimited length fibers of continuous carbon nanotubes and unlimited lengths of large sheets of graphene.

For example, composites such as cables derived from such continuous carbon nanotubes may take advantage of the enormous strength derived from the continuous carbon nanotubes. As electrical cables, they may exhibit low loss and strength over miles for efficient power transmission. Finally, the same approach can synthesize a single band gap semiconducting nanotube for a realistic manufacturing scenario of carbon-based nanotube electronic and optical device components.

As described in greater detail below, to continuously grow a carbon nanotube or graphene sheet in accordance with the aspects of the present invention, a small seed is provided and deposited or dipped into a catalytic melt and pulled slowly to allow growth at the liquid-solid interface. In particular, the catalytic melt acts to catalyze the growth carbon nanotubes and graphene sheets and, in addition, an electrical bias may be applied between the seed and the melt that further aids the growth through electrochemical reaction. This technique may be used to grow single-walled carbon nanotubes (SWNTs), multi-walled carbon nanotubes (MWNTs), graphite, and graphene sheets. Further, the bias may also be used to signal when the seed has touched the melt. This aids when a single nanotube or a single graphene sheet is used as a seed, or generally when visible inspection is not possible.

In addition, the various aspects of the present invention may employ a melt that need not be at the melting point of carbon which typically exceeds 3,500 degrees Celsius. Briefly, the melt may comprise a catalyst or solvent solution. For example, the catalyst or solvent solutions may be maintained at a temperature between about 1,200 degrees Celsius and about 2,500 degrees Celsius, preferably at a temperature of between 1,250 degrees Celsius and about 1,800 degrees Celsius, and desirably at a temperature of about 1,400 degrees Celsius. The melt may be maintained at a pressure below about 1,000,000 psi, in a vacuum, and preferably at a pressure between about 0.001 psi and about 15 psi.

The various aspects of the present invention may result in 1) very long carbon nanotubes cables of with electrical and mechanical properties, 2) individual nanotubes with well defined chirality of sufficient quantity for scaled-up electronic applications, and 3) large sheets of graphene, a material derived from a single sheet of graphite with electronic applications.

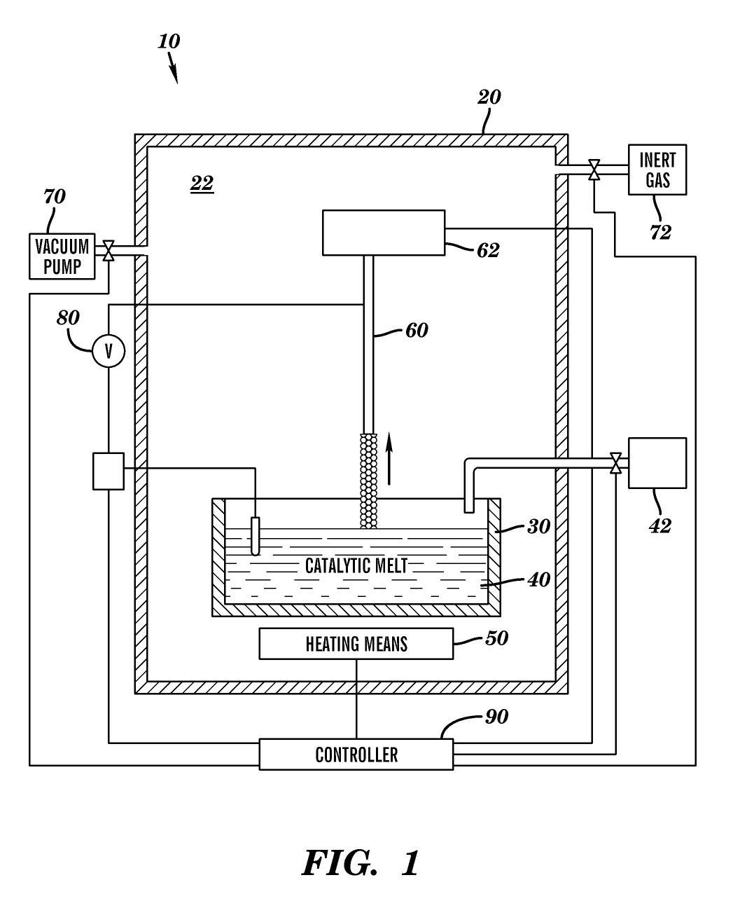

With reference to the figures, FIG. 1 illustrates one embodiment of an apparatus 10 for continuously growing a carbon nanotube in accordance with the one aspect of the present invention. Apparatus 10 generally includes a housing 20 having a chamber 22 therein, a crucible 30, a carbon catalyst solution or melt 40 contained in the crucible, a carbon and catalyst and carbon supply 42 for feeding the melt with additional material, heating means 50 for heating the crucible and melt, a support 60 for supporting a carbon nanotube seed, a mechanism 60 for moving and collecting the continuously grown carbon nanotube, a vacuum pump 70, means 72 for injecting an inert gas into the housing, an electric circuit 80 for applying a voltage between the carbon nanotube seed and/or continuously grown carbon nanotube and the melt, and a controller 90 such as a microprocessor for operably controlling various aspects of the apparatus.

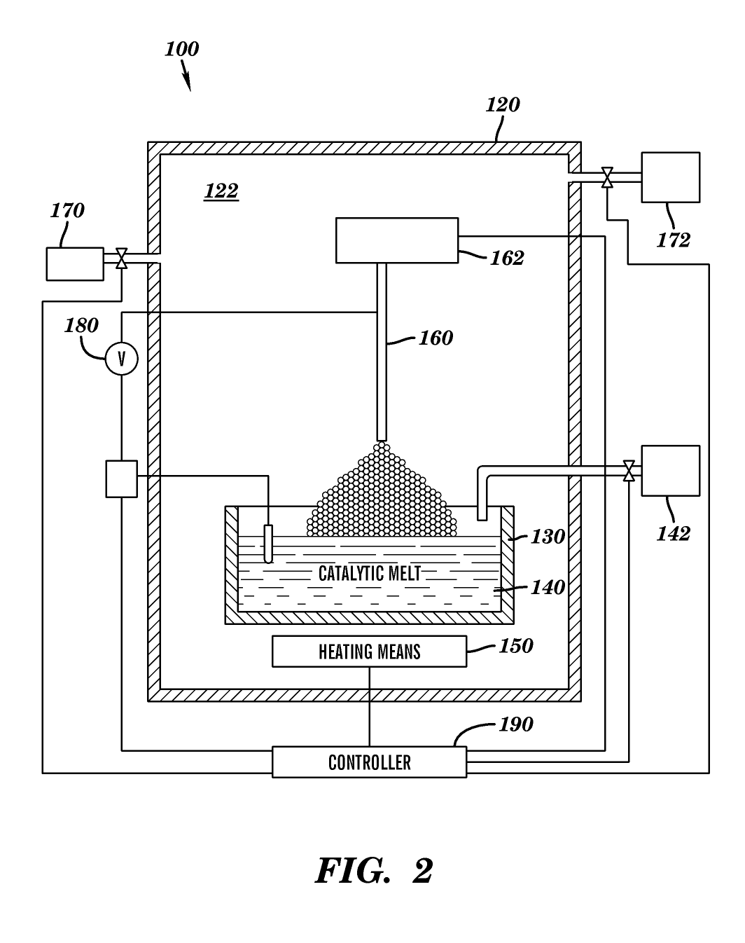

FIG. 2 illustrates one embodiment of an apparatus 100 for continuously growing a graphene sheet in accordance with one aspect of the present invention. Apparatus 100 generally includes a housing 120 having a chamber 122 therein, a crucible 130, a carbon catalyst solution or melt 140 contained in the crucible, a carbon and catalyst and carbon supply 142 for feeding the melt with additional material, heating means 150 for heating the crucible and melt, a support 160 for supporting a graphene seed, a mechanism 160 for moving and collecting the continuously grown graphene sheet, a vacuum pump 170, means 172 for injecting an inert gas into the housing, an electric circuit 180 for applying a voltage between the graphene seed and/or continuously grown graphene sheet and the melt, and a controller 190 such as a microprocessor for operably controlling various aspects of the apparatus.

In the two embodiments, the housing may be formed from stainless steel and may include suitable insulation for maintaining the desired temperature in the housing. The crucible may include a bottom, a surrounding sidewall, and an upper opening. The crucible may be formed from aluminum oxide (Al₂O₃) or other suitable material for holding the heated carbon catalyst melt. The heating means is operable to heat the crucible and the carbon catalyst melt to about 400 degrees Celsius, and may include a suitable electric heating element, graphite heater that can reach temperatures in excess of 2,000 degrees Celsius, or other suitable heating means. The means for injecting an inert gas may be operable to provide high purity argon, other noble gas, or other suitable gas, into the chamber. The support for supporting the carbon nanotube seed or graphene seed may be formed from molybdenum (Mo), tungsten (W), and graphite that is raised and moved away from the crucible. Other supports may be stainless steel. The electric circuit may include a suitable voltage supply such as a battery or a transformer for applying a biasing electrical potential between the melt and the support. Alternatively, the electric circuit may be suitably employed for applying a biasing electrical potential between the melt and the continuously grown carbon nanotube or graphene sheet. The electric circuit may be operably monitored by the controller and the controller may operably lower the carbon nanotube seed into the catalytic melt and upon contact with the surface of the carbon catalytic melt, control the rate of speed at which mechanism raises and collects the carbon nanotube seed and the continuously grown carbon nanotube or graphene seed and the continuously grown graphene sheet upwardly from the carbon catalytic melt. A spool or other suitable collector may collect the continuously grown carbon nanotube or graphene sheet.

The seed may be formed in various ways. For bulk fiber growth, an array of well aligned carbon nanotubes (either multiwalled or single-walled) may be grown on a substrate using a CVD process. The carbon nanotubes may be removed from the substrate, tested to determine its properties, and then selected ones may be attached to the support. For pulling a single nanotube, the starting material will consist of a single nanotube attached to the support. The resulting carbon nanotubes pulled from the catalytic carbon melt reproduce the type of starting material (single or multi-walled). For making large sheets of graphene a small seed of graphene may be used. As the seed is pulled from the melt, the sheet grows in size until it is generally the same width as the crucible. The carbon catalytic melt in addition to lowering the melting point of carbon, may also aid in catalyzing and increasing the rate of growth of carbon nanotubes and graphene sheets. There are various possibilities for the carbon catalytic solution or melt. For example, the carbon catalytic solution or melt may include carbon and a catalyst such as nickel (Ni), cobalt (Co), iron (Fe), etc. The percentage of carbon in the catalytic melt may be between about 2 weight percent of carbon and about 8 weight percent of carbon. The percentage of catalyst in the catalytic melt may be between about 90 weight percent of catalyst and about 99 weight of catalyst. Other co-catalysts may include molybdenum (Mo) and silicon (Si).

The temperature of the carbon catalyst melt may be operated at a temperature of between 1,200 degrees Celsius and about 2,500 degrees Celsius, preferably at a temperature of between 1,250 degrees Celsius and about 1,800 degrees Celsius, and desirably at a temperature of about 1,400 degrees Celsius.

In operation, the basic sequence for pulling a carbon nanotube seed or graphene sheet from a melt may be as follows:
1) The charge (catalysts and graphite mixed in Al₂O₃ crucible) and a seed are loaded into the chamber.
2) The crucible is heated to 400 degrees Celsius in a vacuum to bake-out the charge and the chamber.
3) The chamber is back filled with high purity Argon gas to less than about 50 torr.
4) The crucible temperature is raised until complete melting and mixing occurs. The temperature at which this occurs may depend on the catalyst type and carbon concentration. For example, the temperature may be at between about 1,200 degrees Celsius and about 2,500 degrees Celsius.
5) The carbon nanotube seed or graphene seed is lowered, and the temperature and the pull speed are adjusted to initiate growth. A small section of the carbon nanotube seed or graphene seed is initially melted to expose a clean surface before commencing the pull.

In addition, a bias between the melt and the seed may be applied. The amount of the bias and the resulting current through the nanotube aids in melting the nanotube seed or graphene sheet and aids in the growth process of the resulting continuously grown carbon nanotube or continuously grown graphene sheet. The bias may also be used to determine when the carbon nanotube seed or graphene seed has touched the melt when visible inspection alone is not possible, as expected when using small nanotube seeds such as single nanotubes. For example, a voltage of about 1 volt and about 10 volts, and preferably about 3 volts, and a current density of about 1 microAmp/cm² and about 1,000 Amp/cm², and preferably about 1 Amp/cm², may be applied between the seed and the melt.

The various parameters such as carbon concentration, temperature, ambient pressure, bias voltage (current density) between the melt and carbon nanotube seed or graphene seed, and the pull rate, may be suitably varied. For example, variations in carbon concentration, temperature and pull rate may determine to what extent diffusion of carbon in the melt limits the growth rate of crystals. Different catalysts may aid in determining to what extent reaction at the melt-crystal interface limits the growth rate. The ambient pressure may help control the evaporation of carbon and the catalysts. The materials that are grown may be characterized structurally for their perfection and for determining how faithfully they reproduce the carbon nanotube seed. This may be accomplished by employing SEM, TEM, and Raman spectroscopy, or other imaging and measuring devices, Raman spectroscopy is a tool for characterizing carbon nanotubes. Other metrology tools may be used. For example, a combination of EDX, Auger, and XPS may be used to determine the purity of the pulled carbon nanotube.

It may be suitable to operate the technique for continuously growing carbon nanotubes and graphene sheets at a pressure above atmospheric pressure. For example, the pressure may between about 14.7 psi and about 1,000,000 psi.

Further, other parameters may be varied. For example, a formation of a meniscus at the solid-melt interface may be provided by varying temperature, catalyst composition, carbon concentration, and the pull rate. However, the formation of a meniscus may or may not be needed for the continuous growth of carbon nanotubes and graphene sheets since the reaction is chemically activated.

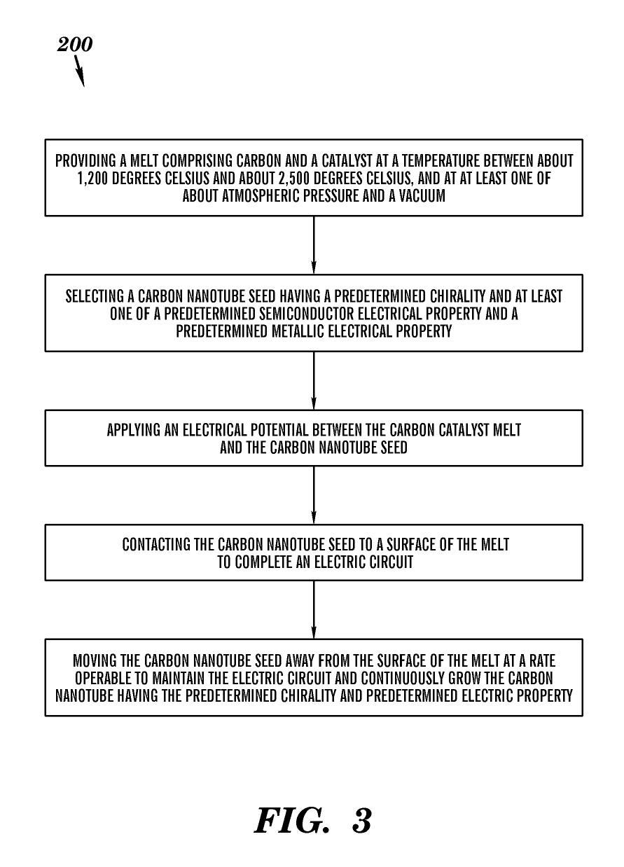

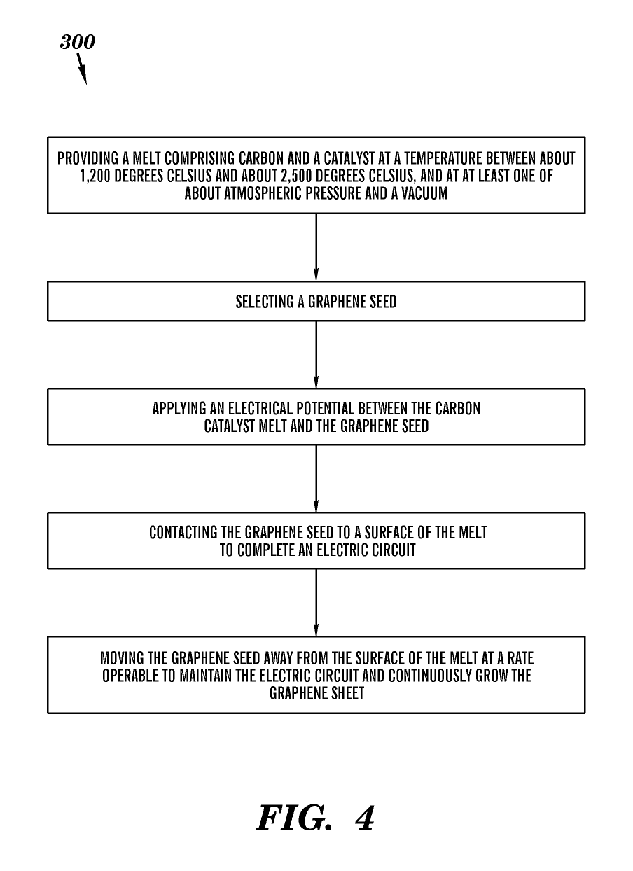

FIG. 3 illustrates one embodiment of a process 200 for continuously growing a carbon nanotube in accordance with one aspect of the present invention. FIG. 4 illustrates one embodiment of a process 300 for continuously growing a graphene sheet in accordance with one aspect of the present invention.

From the present description, it will be appreciated that a plurality of continuous carbon nanotubes and graphene sheets may be pulled at the same time from the same crucible. In addition, the various operations and parameters may be automated and under the control of the controller. The controller such as a suitable processor, microprocessor, or computer may include a suitable processing unit, memory, and various input and output devices.

The process for continuously growing carbon nanotubes may include selecting a carbon nanotube seed having a predetermined chirality, diameter, and electrical property. Generally, three types of nanotubes are possible, called armchair, zigzag and chiral nanotubes, depending on how the two-dimensional graphene sheet is “rolled up”. In chiral nanotubes, the atoms are aligned on a spiral. Besides the chiral angle, the circumference of the cylinder can also be varied. The electronic properties of the carbon nanotubes vary in a predictable way from metallic to semiconducting with diameter and chirality. In the technique for continuously growing carbon nanotubes in accordance with one aspect of the present invention, once the carbon nanotube seed is selected, the continuously grown carbon nanotube does not change and is locked in and has the same diameter and chirality as the carbon nanotube seed. For example, initially the carbon nanotube seed is the master and controls the continuously grown carbon nanotube. Once the continuously grown carbon nanotube begins to form, then the continuously grown carbon nanotube wants to keep its identity, i.e., the same diameter and chirality.

Such continuously grown metallically electric carbon nanotubes may be formed into a cable such as for use in transmission of an electrical current. The process for continuously growing carbon nanotubes may include selecting a carbon nanotube seed having a predetermined semiconductor property. Such continuously grown semiconductor carbon nanotubes may be formed into various electrical components such as transistors, diodes, etc. Continuously grown carbon nanotubes, whether having a predetermined metallic electrical property, semiconductor property, or other property, maybe used as, for example, as high strength fibers in an adhesive or resin binder matrix, to form various high strength products.

The continuously grown graphene sheets may be used in an integrated circuit, transistor, diode, etc. For example, the continuously grown graphene sheet may be layered onto a wafer, glass, metal, plastic, or any suitable flat substrate (attached together via van der Waals attraction or forces) and the integrated circuit built thereon using convention processing techniques with the graphene sheet being the active layer. The continuously grown graphene sheets may also be used in an optoelectronic device such as a photovoltaic cell or light emitting diode. For example, an optoelectronic device may comprise a first optoelectronic material comprising a portion of the continuously grown graphene sheet, a second optoelectronic material attached to said first optoelectronic material, a first electrode attached to said first optoelectronic material, and a second electrode attached to said second optoelectronic material.

Although the invention has been particularly shown and described with reference to certain preferred embodiments, it will be readily appreciated by those of ordinary skill in the art that various changes and modifications may be made therein, without departing from the spirit and scope of the invention.

1. An apparatus for continuously growing a carbon nanotube from a carbon nanotube seed, said apparatus comprising:
a housing having a chamber;
crucible for containing a carbon catalyst melt disposed in said chamber of said housing;
heating means for heating the carbon catalyst melt to a temperature between about 1,200 degrees Celsius and about 2,500 degrees Celsius; and
a controller for controlling movement of the carbon nanotube seed to contact a surface of the carbon catalyst melt and controlling movement of the carbon nanotube seed away from the surface of the carbon catalyst melt maintained at the temperature between about 1,200 degrees Celsius and about 2,500 degrees Celsius and at a rate operable to continuously grow the carbon nanotube.

2. The apparatus of claim 1 further comprising means for applying an electrical potential between the melt and carbon nanotube seed, and wherein said controller is operable to control movement of the carbon nanotube seed to contact the surface of the melt in said crucible upon competing an electric circuit between the melt and the carbon nanotube seed and controlling movement of the carbon nanotube seed away from the surface of the melt at the rate operable to maintain the electric circuit and continuously grow the carbon nanotube.

3. The apparatus of claim 1 further comprising means for maintaining a pressure in said chamber of said housing below about 1,000,000 psi.

4. The apparatus of claim 1 further comprising means for maintaining a pressure in said chamber of said housing in a vacuum.

5. The apparatus of claim 1 further comprising means for maintaining a pressure in said chamber of said housing between about 0.001 psi and about 15 psi.

6. The apparatus of claim 1 further comprising means for injecting an inert gas into said chamber in said housing.

7. The apparatus of claim 1 further comprising means for collecting the continuously grown carbon nanotube.

8. The apparatus of claim 1 wherein said crucible comprises aluminum oxide.

9. A method for continuously growing a carbon nanotube, the method comprising:
providing a melt comprising carbon and a catalyst at a temperature between about 1,200 degrees Celsius and about 2,500 degrees Celsius;
selecting a carbon nanotube seed having at least one of a semiconductor electrical property and a metallic electrical property from a plurality of carbon nanotube seeds;
contacting the selected carbon nanotube seed to a surface of the melt;
moving the selected carbon nanotube seed away from the surface of the melt at a rate operable to continuously grow a carbon nanotube; and
continuously growing the carbon nanotube having the selected electrical property.

10. The method of claim 9 further comprising applying an electrical potential between the carbon catalyst melt and the carbon nanotube seed, and wherein the contacting the carbon nanotube seed to a surface of the melt completes an electric circuit, and wherein moving the carbon nanotube seed away from the surface of the melt at the rate operable to maintain the electric circuit and continuously grow the carbon nanotube having the selected electric property.

11. The method of claim 9 further comprising maintaining the carbon catalyst melt at a pressure below about 1,000,000 psi.

12. The method of claim 9 further comprising maintaining a pressure in said chamber of said housing in a vacuum.

13. The method of claim 9 further comprising maintaining the carbon catalyst melt at a pressure between about 0.001 psi and about 15 psi.

14. The method of claim 9 wherein selecting comprises selecting a carbon nanotube seed having the metallic electrical property.

15. The method of claim 9 wherein selecting comprises selecting a carbon nanotube seed having the semiconductor electrical property.

16. The method of claim 9 wherein the catalytic carbon melt comprises carbon and at least one of nickel, cobalt, and iron.

17. The method of claim 9 wherein the percentage of carbon in the catalytic melt is between about 2 weight percent of carbon and about 8 weight percent of carbon.

18. The method of claim 9 wherein the percentage of catalyst in the catalytic melt is between about 90 weight percent of catalyst and about 99 weight of catalyst.

19. The method of claim 9 further comprising forming a plurality of the continuously grown carbon nanotubes into an electrical cable.

20. The method of claim 9 further comprising forming a product having a plurality of the continuously grown carbon nanotubes as high strength fibers.

21. An electric cable comprising:
a plurality of continuously grown carbon nanotubes formed from the method of claim 9.

22. A composite product comprising:
a binder and a plurality of continuously grown carbon nanotubes formed from the method of claim 9.

23. An apparatus for continuously growing a graphene sheet from a graphene seed, said apparatus comprising:
a housing having a chamber;
crucible for containing a carbon catalyst melt disposed in said chamber of said housing;
heating means for heating the carbon catalyst melt to a temperature between about 1,200 degrees Celsius and about 2,500 degrees Celsius; and
a controller for controlling movement of the graphene seed to contact a surface of the carbon catalyst melt and controlling movement of the graphene seed away from the surface of the carbon catalyst melt at the temperature between about 1,200 degrees Celsius and about 2,500 degrees Celsius and at a rate operable to continuously grow the graphene sheet.

24. The apparatus of claim 23 further comprising means for applying an electrical potential between the melt and graphene seed, and wherein said controller is operable to control movement of the graphene seed to contact the surface of the melt in said crucible upon competing an electric circuit between the melt and the graphene seed and controlling movement of the graphene seed away from the surface of the melt at the rate operable to maintain the electric circuit and continuously grow the graphene sheet.

25. The apparatus of claim 23 further comprising means for maintaining a pressure in said chamber of said housing below about 1,000,000 psi.

26. The apparatus of claim 23 further comprising means for maintaining a pressure in said chamber of said housing in a vacuum.

27. The apparatus of claim 23 further comprising means for maintaining a pressure in said chamber of said housing between about 0.001 psi and about 15 psi.

28. The apparatus of claim 23 further comprising means for injecting an inert gas into said chamber in said housing.

29. The apparatus of claim 23 further comprising means for collecting the continuously grown graphene sheet.

30. The apparatus of claim 23 wherein said crucible comprises aluminum oxide.

31. A method for continuously growing a graphene sheet, the method comprising:
providing a melt comprising carbon and a catalyst at a temperature between about 1,200 Celsius and about 2,500 degrees Celsius;
providing a graphene seed;
contacting the graphene seed to a surface of the melt;
moving the graphene seed away from the surface of the melt at a rate operable to continuously grow the graphene sheet; and
continuously growing the graphene sheet.

32. The method of claim 31 further comprising applying an electrical potential between the carbon catalyst melt and the graphene seed, and wherein the contacting the graphene seed to a surface of the melt completes an electric circuit, and wherein moving the graphene seed away from the surface of the melt at the rate is operable to maintain the electric circuit and continuously grow the graphene sheet.

33. The method of claim 31 further comprising maintaining the carbon catalyst melt at a pressure below about 1,000,000 psi.

34. The method of claim 31 further comprising maintaining a pressure in said chamber of said housing in a vacuum.

35. The method of claim 31 further comprising maintaining the carbon catalyst melt at a pressure between about 0.001 psi and about 15 psi.

36. The method of claim 31 wherein the catalytic carbon melt comprises carbon and at least one of nickel, cobalt, and iron.

37. The method of claim 31 wherein the percentage of carbon in the catalytic melt is between about 2 weight percent of carbon and about 8 weight percent of carbon.

38. The method of claim 31 wherein the percentage of catalyst in the catalytic melt is between about 90 weight percent of catalyst and about 99 weight of catalyst.

39. The method of claim 31 further comprising forming an integrated circuit with the continuously grown graphene sheet.

40. The method of claim 31 further comprising forming an optoelectronic device with the continuously grown graphene sheet.

41. The method of claim 31 further comprising forming a photovoltaic cell with the continuously grown graphene sheet.

42. The method of claim 31 further comprising forming a light emitting diode with the continuously grown graphene sheet.

43. An integrated circuit comprising:
the continuously grown graphene sheet formed from the method of claim 31.

44. An optoelectronic device comprising:
a first optoelectronic material comprising the continuously grown graphene sheet of formed from the method of claim 31;
a second optoelectronic material attached to said first optoelectronic material;
a first electrode attached to said first optoelectronic material; and
a second electrode attached to said second optoelectronic material.

45. The optoelectronic device of claim 44 wherein said optoelectronic device comprises a photovoltaic cell.

46. The optoelectronic device of claim 44 wherein said optoelectronic device comprises a light emitting diode.
